(19) United States
(12) Patent Application Publication
(10) Pub. No.: US 2025/0308977 A1
(43) Pub. Date: Oct. 2, 2025

(54) ECCENTRICITY BASED WAFER SHAPE CONTROL

(71) Applicant: Tokyo Electron Limited, Tokyo (JP)

(72) Inventor: Joshua HOOGE, Austin, TX (US)

(73) Assignee: Tokyo Electron Limited, Tokyo (JP)

(21) Appl. No.: 18/620,178

(22) Filed: Mar. 28, 2024

(51) Int. Cl. H01L 21/687; H01L 21/67

(52) U.S. Cl. CPC H01L 21/68764; H01L 21/6715

(57) ABSTRACT

Aspects of the present disclosure provide an apparatus for forming a shape control layer at an edge region of a wafer with respect to a rotational axis of the chuck. For example, the apparatus can include a chuck configured for a wafer to be off-center placed thereon. The apparatus can also include a film formation device configured to dispense on a surface of the wafer a shape control material that has its internal stress modified when reactive to a certain type of reaction. The chuck can be configured to rotate with respect to the film formation device.

### FIELD OF THE INVENTION

The present disclosure relates to semiconductor fabrication, and, more particularly, to eccentricity based wafer shape control.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

Exposure systems (also called tools) are used to implement photolithographic techniques. An exposure system typically includes an illumination system, a reticle (also called a photomask) or spatial light modulator (SLM) for creating a circuit pattern, a projection system, and a wafer alignment stage for aligning a photosensitive resist-covered semiconductor wafer. The illumination system illuminates a region of the reticle or SLM with a (preferably) rectangular slot illumination field. The projection system projects an image of the illuminated region of the reticle pattern onto the wafer. For accurate projection, it is important to expose a pattern of light on a wafer that is relatively flat or planar, preferably having less than 10 microns of height deviation.

### SUMMARY

Aspects of the present disclosure provide an apparatus for forming a shape control layer at an edge region of a wafer. For example, the apparatus can include a chuck configured for a wafer to be off-center placed thereon. The apparatus can also include a film formation device configured to dispense on a surface of the wafer a shape control material that has its internal stress modified when reactive to a certain type of reaction. The chuck can be configured to rotate with respect to the film formation device. In an embodiment, the internal stress of the shape control material can be modified to become compressive. In another embodiment, the internal stress of the shape control material can be modified to become tensile. In some embodiments, the internal stress of a first portion of the shape control material is modified to become tensile, and the internal stress of a second portion of the shape control material is modified to become compressive.

In an embodiment, the wafer can be placed on the chuck such that a wafer center of the wafer is located at a first location or a second location with respect to a chuck center of the chuck. For example, the first location and the second location can be separated from the chuck center of the chuck at a same distance. As another example, the first location and the second location can be separated from the chuck center of the chuck at different distances. For example, the first location and the second location can be arranged in a line that passes the chuck center of the chuck. As another example, the first location and the second location can be arranged in a line that does not pass the chuck center of the chuck.

In an embodiment, the film formation device can include a dispense nozzle that is located over an edge region of the wafer and configured to dispense the shape control material at the edge region of the wafer.

In an embodiment, the chuck can be further configured to move with respect to the film formation device. For example, the chuck can be configured to vibrate with respect to the film formation device. As another example, the chuck can be configured to move along a track with respect to the film formation device.

Aspects of the present disclosure further provide a method of processing a wafer. For example, the method can include placing a wafer on a chuck with the wafer being positioned off-center with respect to a rotational axis of the chuck, positioning a dispense nozzle over an edge region of the wafer when placed on the chuck, rotating the chuck with the wafer placed thereon with respect to the dispense nozzle such that as the wafer rotates a first portion of the edge region of the wafer passes under the dispense nozzle while a second portion of the edge region of the wafer does not pass under the dispense nozzle as a function of the wafer being positioned off-center, and dispensing a shape control material from the dispense nozzle, the shape control material coating a surface of the first portion of the edge region without coating the second portion of the edge portion.

In an embodiment, the first portion and the second portion can have a same maximum width. In another embodiment, the first portion and the second portion can have different maximum widths. In some embodiments, the first portion and the second portion can be opposite to each other.

In an embodiment, rotating the chuck with the wafer placed thereon with respect to the dispense nozzle can include rotating and moving the chuck with the wafer placed thereon with respect to the dispense nozzle. In another embodiment, rotating and moving the chuck with the wafer placed thereon with respect to the dispense nozzle can include rotating and vibrating the chuck with the wafer placed thereon with respect to the dispense nozzle. In some embodiments, the chuck can be moved along a track with respect to the dispense nozzle includes.

In an embodiment, the wafer can be placed on the chuck such that a wafer center of the wafer is located at a first location or a second location with respect to a chuck center of the chuck. In another embodiment, the method can also include dispensing the shape control material from the dispense nozzle, the shape control material coating a surface of the second portion of the edge portion.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A to 1C show first and second order bowing of a wafer;

FIGS. 2A and 2B show low order global wafer distortion and high order local wafer distortion, respectively;

FIG. 3 is a plan view of an exemplary wafer processing system for correcting or modifying wafer bow according to some embodiments of the present disclosure;

FIGS. 4A-4C illustrate an exemplary apparatus for forming a shape control layer at an edge region of a wafer according to some embodiments of the present disclosure;

FIGS. 5A-5D illustrate an exemplary apparatus for forming two or more shape control layers at an edge region of a wafer according to some embodiments of the present disclosure;

FIGS. 6A and 6B illustrate the formation of a shape control layer at an edge region of a wafer;

FIGS. 7A and 7B illustrate an exemplary apparatus for forming a shape control layer at an edge region of a wafer according to some embodiments of the present disclosure; and

FIG. 8 is a flow chart of an exemplary method for forming a shape control layer at an edge region of a wafer according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

A functional semiconductor wafer can be comprised of the integration of 70±individual layers that ultimately culminate in functional semiconductor devices. Each level requires multiple processing steps including, but not limited to thin film deposition, lithography and etches to form the desired structures. Non-uniform wafer stresses induced through these operations result from the patterning of thin films and are amplified via multiple temperature cycling processes, fundamentally distorting the wafer grid and creating unique wafer shapes throughout the entire integration.

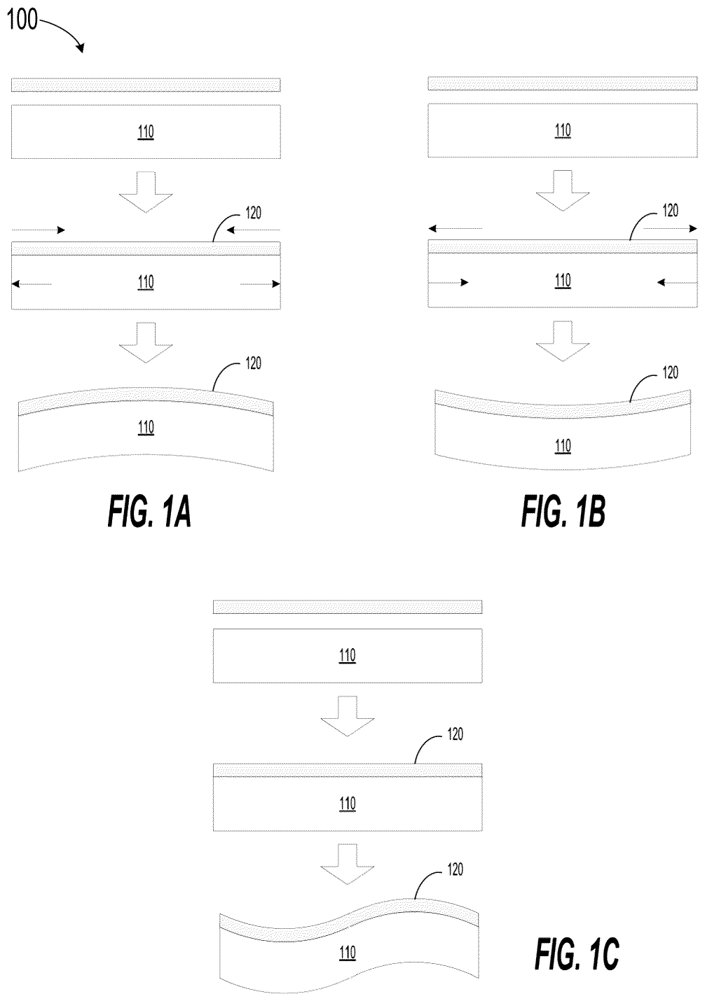

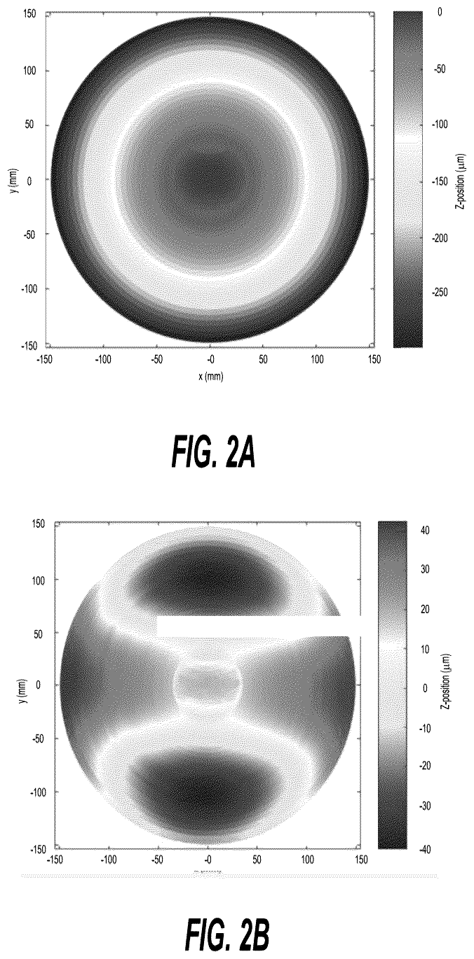

For example, microfabrication of a semiconductor structure 100 begins with a flat substrate or wafer 110, as those illustrated in FIGS. 1A to 1C. During microfabrication of the semiconductor structure 100, multiple processing steps are executed that can include depositing material on the wafer 110, removing material, implanting dopants, annealing, baking, and so forth. Different materials and structural formations 120 thus formed can induce non-uniform wafer stresses, which result in bowing of the semiconductor structure 100, which in turn affects overlay and typically results in overlay errors of various magnitudes. For example, FIGS. 1A and 1B show how the different materials and structural formations 120 can either induce a compressive or tensile stress in the wafer 110, respectively, resulting in first order bowing with bow measurements illustrating z-direction height (or z-height) deviations from a reference plane (not shown). As another example, FIG. 1C shows second order bowing of the wafer 110 with two bow measurements identifying positive and negative z-height deviations, respectively. The non-uniform wafer stresses fundamentally distort the wafer grid. These distortions can manifest as low order global spherical type deformations as depicted in FIG. 2A, which shows z-height variations on 300 nm semiconductor wafers. Higher order localized z-height variations may exist as stand-alone distortions or may be embedded in the global signature. An example of a higher order wafer deformation is presented in FIG. 2B. The data presented is derived from standard semiconductor metrology equipment common to the industry. Both low and high order wafer shapes can complicate subsequent processes, e.g., a bonding process, and negatively impact yield.

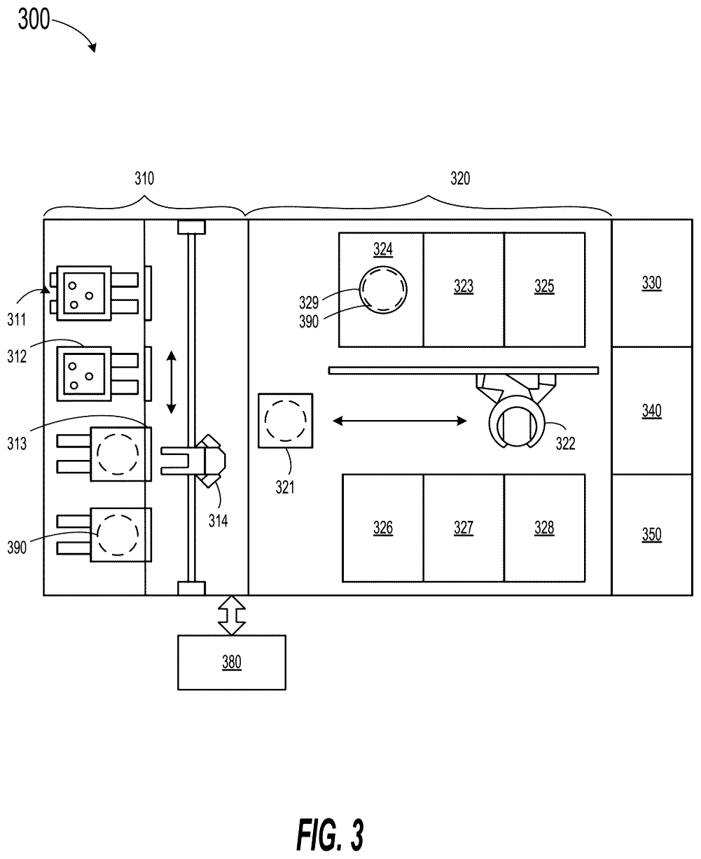

FIG. 3 is a plan view of an exemplary wafer processing system 300, e.g., a track lithography tool, for correcting or modifying bow of a wafer (and die or chiplet) and controlling the shape of the wafer in accordance with some embodiments of the present disclosure. The wafer processing system 300 includes various wafer handling components or carriers, along with several stages, e.g., a carrier stage 310 and a treatment stage 320. The carrier stage 310 can include one or more pod assemblies 311 that are configured to receive one or more wafer cassettes 312 that are configured to contain one or more wafers 390, e.g., the wafer 110 shown in FIGS. 1A to 1C, that are to be processed in the wafer processing system 300. In an embodiment, the wafer cassettes 312 can be further configured to accept already diced chiplets stored on either tape or frame. Doors 313 can open to access the wafers 390 contained in the wafer cassettes 312. A carrier transfer robot 314 can move up and down and transfer the wafer 390 from the wafer cassettes 312 to a shelf unit 321 that is installed in the treatment stage 320 for storing the wafer 390 temporarily.

The treatment stage 320 includes a variety of treatment devices, e.g., treatment devices 323-328, and a treatment transfer robot 322. The treatment transfer robot 322 can be configured to access the shelf unit 321 and the treatment devices 323-328 and transfer the wafer 390 among the treatment devices 323-328 for various processing. In an embodiment, the treatment transfer robot 322 can flip and/or rotate the wafer 390. The treatment devices 323-328 can include one or more metrology devices 323, which are configured to measure an amount of wafer bow of the wafers 390 and provide bow measurements to the wafer processing system 300. In an embodiment, the metrology devices 323 can use optical (e.g., using a scanning laser technique), acoustic and other mechanisms to measure the z-height deviations across a surface of the wafer 390 and store the height deviations by (x, y) coordinates to identify a plurality of sub-bow measurements (x, y) of the bow measurement. Bow measurements can include measuring a degree of convexity or concavity, or mapping z-height deviation values on the wafers 390 relative to one or more reference z-height deviation values. In other words, z-height deviation values are spatially mapped, such as with coordinate locations, to identify z-height deviation values across a surface of the wafer 390. Bow measurements and z-height deviation values can be mapped at various resolutions depending on types of metrology equipment used and/or a resolution desired. In an embodiment, the metrology devices 323 can also measure the amount of die bow of each of dies that are obtained by dicing and singulating the wafer 390.

The bow (and die) measurements can include raw bow data or be represented as a bow signature with relative z-height deviation values. In some embodiments, the reference z-height deviation values may be all close to zero and thus representative of a wafer that is close to being flat. For example, a wafer that is close to being flat or considered flat for overlay improvement herein can be a wafer having an average z-height deviation value of less than 1 μm. In various embodiments, the reference z-height deviation values can represent some non-planar shape, but which shape is, notwithstanding, useful for overlay error correction—especially for particular stages of micro fabrication. Techniques herein enable correction of bowing that is greater than 1 μm, for example. The metrology device 323 can be configured to measure the wafer 390, which has a working (or frontside) surface and a backside surface opposite to the working surface. The wafer 390 may have an initial wafer bow value resulting from one or more micro fabrication processing steps that have been executed to create at least part of a semiconductor device on the working surface of the wafer 390. For example, field-effect transistors (FETs) may be completed or only partially completed on the working surface of the wafer 390.

The treatment devices 323-328 can also include one or more film formation devices 324 that are configured to form one or more films, e.g., a shape control layer (or a stressor film), on a surface (e.g., the working surface or backside surface) of the wafer 390 being processed. In an embodiment, the film formation device 324 can be configured to form a shape control layer on the working surface and/or backside surface of the wafer 390 using chemical vapor deposition (CVP), atomic layer deposition (ALD), spin-on film deposition process, or other deposition techniques. For example, in the spin-on film deposition process an amount of a shape control material is deposited on the backside surface of the wafer 390 while the wafer 390, which may be flipped over by the treatment transfer robot 322 and placed on a wafer chuck (e.g., a vacuum spin chuck) 329, is rotating, thus causing a solvent in the shape control material to evaporate and the properties of the deposited shape control material to change, to promote the adhesion of the shape control material to the backside surface of the wafer 390. The shape control material can be any combination of films such as oxides, nitrides and/or spin-on films present on the backside surface of the wafer 390. In an embodiment, the film formation device 324 can further perform a lithographic process on the shape control material. For example, the lithographic process can include depositing and forming a resist layer on the shape control material, exposing the resist layer to radiation or heat, developing a portion of the resist layer that has been exposed to the radiation of heat, transferring the pattern of the remaining resist layer to the shape control material by etching the shape control material to form the patterned shape control material, and removing the remaining resist layer. The film formation device 324 and the metrology device 323 can be installed on a common platform having an automated wafer handling system that automatically moves the wafer 390 from the metrology device 323 to the film formation device 324.

In an embodiment, the shape control material can include a heat sensitive material, which, when reactive to heat, may have its internal stress modified by the heat to become compressive, neutral or tensile. In another embodiment, the shape control material can include a photosensitive material, which, when exposed to actinic radiation or light, absorbs light in the desired or required energy spectrum and exhibits a chemical/physical reaction that allows applications at different fields.

The treatment devices 323-328 can also include one or more bake devices 325 that are configured to bake the wafer 390 to a target temperature. For example, the bake device 325 can bake and stabilize the wafer 390 at 32° C. or 90° C. As another example, the bake device 325 can bake the wafer 390 with a shape control material (e.g., a heat sensitive material) formed thereon using a pattern of heat that correspond to a bow measurement of the wafer 390, to correct or modify an internal stress of the shape control material, thus forming a shape control layer that may be compressive or tensile. The treatment devices 323-328 can also include one or more activation devices, which are configured to generate a certain type of activation, to which the shape control material is reactive. For example, the treatment devices 323-328 can also include one or more radiation sources 326 that are configured to project onto different regions of the shape control material radiations of variable intensities that correspond to the bow measurement of the wafer 390. As another example, the treatment devices 323-328 can also include a plurality of heating units 327, which can be installed on a wafer chuck (e.g., a vacuum spin chuck) that is used for a wafer to be placed thereon. The heating units 327 can have an arrangement corresponding to a certain pattern of heat and generate different temperature ranges of heat, and the wafer chuck can thus have a plurality of heating zones that correspond to the certain pattern of heat. Accordingly, the shape control material can be heated in different regions that correspond to the certain pattern of heat such that the stresses of the shape control material combined with the wafer in the different regions can be modified to become compressive or tensile, thus forming the shape control layer that may be compressive or tensile. In some embodiments, the treatment devices 323-328 can also include a laser source 328, e.g., a direct laser write source, which can provide localized heating to the shape control material such that the stresses of the shape control material in different regions can be modified to become compressive or tensile, thus forming a shape control layer that may be compressive or tensile.

The wafer processing system 300 further includes a controller 380. The controller 380 can be a computer processor located within the wafer processing system 300, or located remotely but being in communication with components of the wafer processing system 300, e.g., the metrology device 323, the film formation device 324, the bake device 325, the radiation source 326, the heating units 327 and the laser source 328. In an embodiment, the controller 380 can be configured to control the metrology device 323 to measure the wafer 390 to identify a bow measurement of the wafer 390 (and/or measure a die to identify a bow measurement of the die), receive the bow measurement from the metrology device 323, control the film formation device 324 to form a shape control material on the backside surface (or working surface or both) of the wafer 390, control the bake device 325 to differentially bake the wafer 390 with the shape control material formed thereon using a pattern of heat that corresponds to the bow measurement of the wafer 390, control the radiation source 326 to project on different regions of the shape control material radiations of variable intensities that correspond to the bow measurement of the wafer 390, control the heating units 327 to generate different temperature ranges of heat that correspond to the a certain pattern of heat that corresponds to the bow measurement of the wafer 390, and/or control the laser source 328 to provide localized heating to the shape control material, to correct or modify the internal stress of the shape control material (or stressor film) to become compressive or tensile, thus forming a shape control layer that may be compressive or tensile.

The wafer processing system 300 can also include other stages or components, e.g., a stepper/scanner 330, a singulation device 340 and a bonding tool 350. In an embodiment, the stepper/scanner 330 can be detached from the treatment stage 320 since the throughput of the stepper/scanner 330 is often many times greater than the throughput of the carrier stage 310 and the treatment stage 320, and thus dedicating the stepper/scanner 330 to a single treatment stage wastes the stepper/scanner's excess throughput capacity. The singulation device 340 can be configured to dice and singulate a wafer, with or without a shape control layer formed thereon, to obtain a plurality of chiplets. The bonding tool 350 can be configured to connect (join) an integrated chiplet (or die or wafer) with a wafer together in one mechanically stable package. The bonding tool 350 can employ direct wafer bonding (such as fusion bonding and anodic bonding) or wafer bonding with intermediate material (such as solder bonding and eutectic bonding) to bond a wafer/chiplet with a wafer/chiplet. In the example embodiment shown in FIG. 3, the film formation device 324, the bake device 325, the radiation source 326, the heating units 327 and the laser source 328 that perform the shape control process are integrated as a standalone platform. In another embodiment, one or more of the film formation device 324, the bake device 325, the radiation source 326, the heating units 327 and the laser source 328 can be integrated with the bonding tool 350.

The shape (e.g., due to bowing) of a wafer (e.g., the wafer 390) may affect overlay, and it is difficult for a scanner (e.g., the scanner 330) to correct at an edge region of the wafer 390. Aspects of the present disclosure provide means to vary stress around the edge region of a wafer to optimize overlay. In an embodiment, shell hardware/software can be used to adjust the position of a wafer placed on a chuck such that a film, e.g., shape control layer, can be dispensed and formed at the edge region of the wafer. In some embodiments, a combination of off-center wafer placements and dispenses while rotating can be used to purposely skew the coating or deposition of the shape control layer to create tensile or compressive stress at one or more sections of the edge region of the wafer.

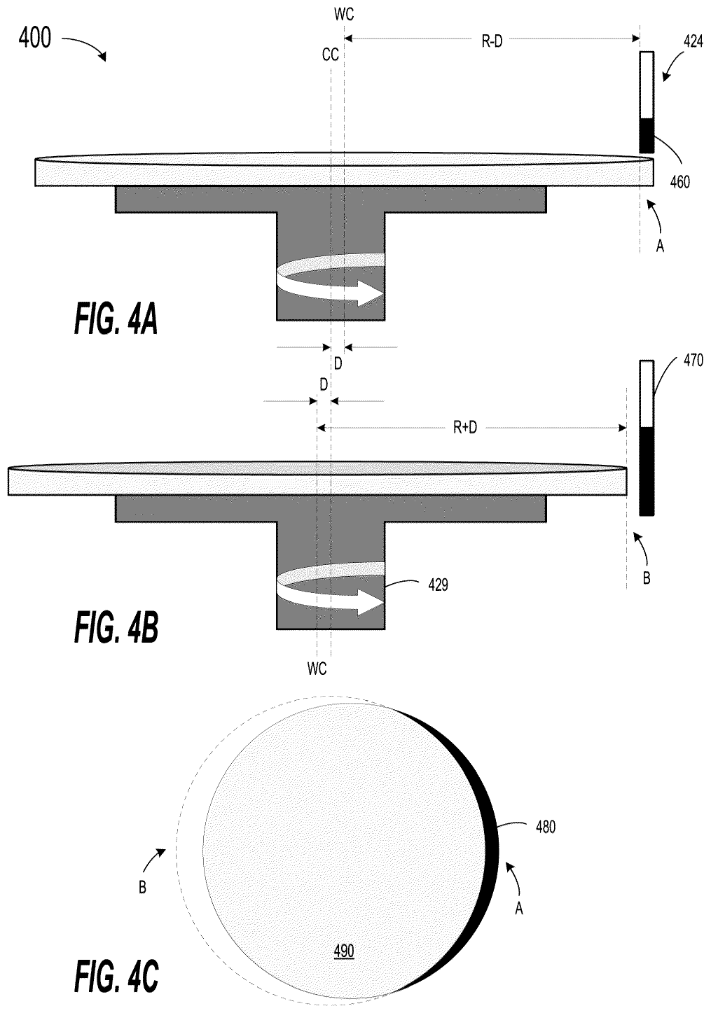

FIGS. 4A-4C illustrate an exemplary apparatus 400 for forming a shape control layer 480 at an edge region of a wafer 490 (e.g., the wafer 390) according to some embodiments of the present disclosure. In an embodiment, the apparatus 400 can include a film formation device 424 (e.g., the film formation device 324) that is configured to dispense a material (e.g., a shape control material) (e.g., via a dispense nozzle 470) and form a film (e.g., the shape control layer 480) on a surface (e.g., a backside surface) of the wafer 490, and a chuck 429 (such as a vacuum spin chuck, e.g., the vacuum spin chuck 329) that is configured for a wafer (e.g., the wafer 490) to be placed thereon. In some embodiments, the wafer 490 can be placed off-center on the chuck 429 with respect to a rotational axis of the chuck 429 and the chuck 429 and the film formation device 424 (and the wafer 490 and the dispense nozzle 470 as well) can rotate with respect to each other. For example, the center CC of the chuck 429 may be separated from the center WC of the wafer 490 at an offset D and separated from the dispense nozzle 470 at a distance R (e.g., the radius of the wafer 490), as shown in FIGS. 4A and 4B.

Therefore, when the chuck 429 rotates with respect to the film formation device 424 (i.e., with respect to the dispense nozzle 470) and the wafer 490 off-center placed on the chuck 429 is in a first position A where the center WC of the wafer 490 is spaced from the dispense nozzle 470 at a distance R-D, which is shorter than the distance R, the shape control material 460 is dispensed and the shape control layer 480 is formed at the edge region of the wafer 490 (e.g., formed at a first portion of the edge region of the wafer 490), and when the chuck 429 rotates with respect to the film formation device 424 (i.e., with respect to the dispense nozzle 470) and the wafer 490 off-center placed on the chuck 429 is in a second position B (e.g., opposite to the first position A) where the center WC of the wafer 490 is spaced from the dispense nozzle 470 at a distance R+D, which is longer than the distance R, the shape control material 460 will not be dispensed and the shape control layer 480 will not be formed on the wafer 490 (e.g., without being formed at a second portion of the edge region of the wafer 490), as shown in FIG. 4C. As a result, one skew (e.g., crescent) shape control layer 480 can be formed at the edge region of the wafer 490. In an embodiment, the maximum width of the crescent shape control layer 480 is related to the offset D. For example, the maximum width of the crescent shape control layer 480 can be equal to the offset D.

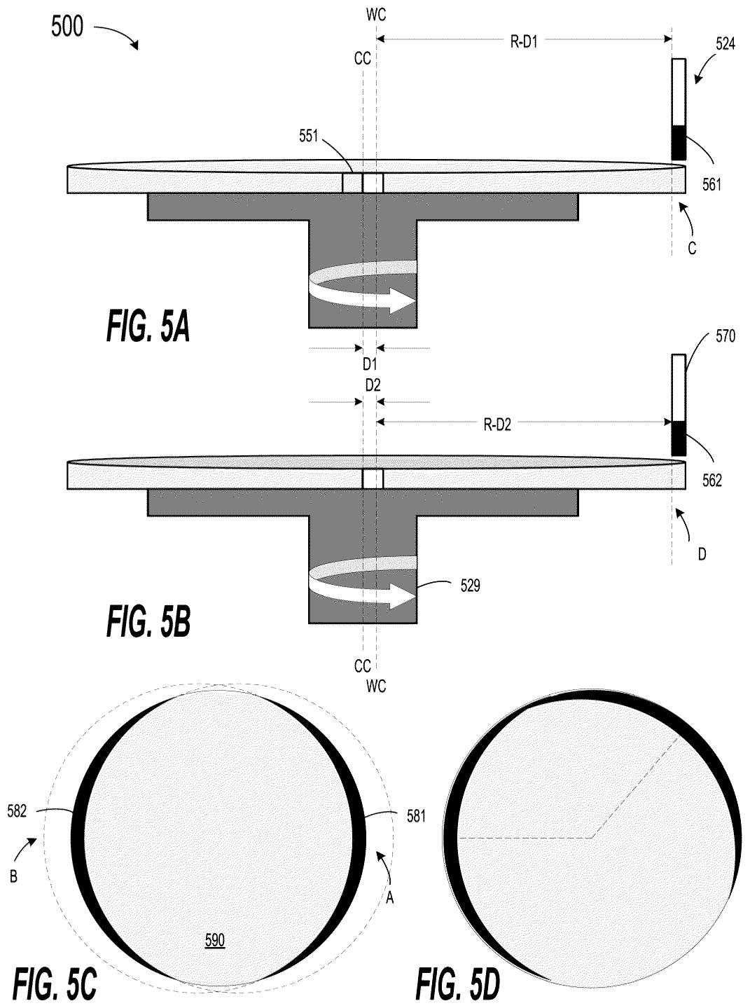

FIGS. 5A-5D illustrate an exemplary apparatus 500 for forming two or more shape control layers (e.g., first and second shape control layers 581 and 582) at an edge region of a wafer 590 (e.g., the wafer 390) according to some embodiments of the present disclosure. In an embodiment, the apparatus 500 can include a film formation device 524 (e.g., the film formation devices 324 and 424) that is configured to dispense a material (e.g., first and second shape control materials 561 and 562) (e.g., via a dispense nozzle 570) and form a film (e.g., the first and second shape control layers 581 and 582) on a surface (e.g., a backside surface) of the wafer 590, and a chuck 529 (such as a vacuum spin chuck, e.g., the vacuum spin chucks 329 and 429) that is configured for a wafer, e.g., the wafer 590, to be placed thereon. In some embodiments, the wafer 590 can be placed off-center on the chuck 529 with respect to a rotational axis of the chuck 529, and the chuck 529 and the film formation device 524 (and the wafer 590 and the dispense nozzle 570 as well) can rotate with respect to each other.

For example, the wafer 590 can be off-center placed on the chuck 529 with respect to the rotational axis of the chuck 529 with a wafer notch (or wafer flatness) 551 facing a first direction (e.g., a front side) and the center CC of the chuck 529 being separated from the center WC of the wafer 590 at a first offset D1 and separated from the dispense nozzle 570 at a distance R (e.g., the radius of the wafer 590), as shown in FIG. 5A; and when the chuck 529 (and the wafer 590 as well) rotates with respect to the film formation device 524 (i.e., with respect to the dispense nozzle 570) and the wafer 590 off-center placed on the chuck 529 is in a third position C where the center WC of the wafer 590 is spaced from the dispense nozzle 570 at a distance R-D1, which is shorter than the distance R, the first shape control material 561 is dispensed and the first shape control layer 581 is formed at a first portion of the edge region of the wafer 590, as shown in FIG. 5C.

As another example, after the first shape control material 581 is formed, the wafer 590 can be off-center placed on the chuck 529 with respect to the rotational axis of the chuck 529 with the wafer notch (or wafer flatness) 551 facing a second direction (e.g., a back side) and the center CC of the chuck 529 being separated from the center WC of the wafer 590 at a second offset D2 and separated from the dispense nozzle 570 at the distance R (e.g., the radius of the wafer 590), as shown in FIG. 5B; and when the chuck 529 (and the wafer 590 as well) rotates with respect to the film formation device 524 (i.e., with respect to the dispense nozzle 570) and the wafer 590 off-center placed on the chuck 529 is in a fourth position D where the center WC of the wafer 590 is spaced from the dispense nozzle 570 at a distance R-D2, which is shorter than the distance R, the second shape control material 561 is dispensed and the second shape control layer 581 is formed at a second portion of the edge region of the wafer 590, as shown in FIG. 5C.

In an embodiment, the first offset D1 may be equal to or different from the second offset D2. Therefore, the crescent first shape control layer 581 and the crescent second shape control layer 582 may be in the same or different widths in maximum. In the example embodiment shown in FIGS. 5A-5C, the first direction and the second direction that the wafer notch 551 of the wafer 590 faces are opposite to each other. In some embodiments, the first direction and the second direction can have an included angle of any degrees, e.g., 120 degrees, and two corresponding shape control layers thus formed are not opposite to each other, as shown in FIG. 5D.

In an embodiment, a shape control layer may be formed in a positive manner onto the edge region of a wafer. For example, after one or more shape control materials (e.g., the shape control material 460 and the first and second shape control materials 561 and 562) have been deposited and formed on a surface (e.g., the backside surface) of a wafer (e.g., the wafers 490 and 590), an activation device (e.g., the radiation source 326, the heating units 327 and the laser source 328) can be used to provide a certain pattern of activation (e.g., radiations of variable intensities, a certain pattern of heat and localized heat) to the shape control material such that the stresses of the shape control material can be modified to become compressive or tensile and a corresponding shape control layer that may be compressive or tensile can be formed.

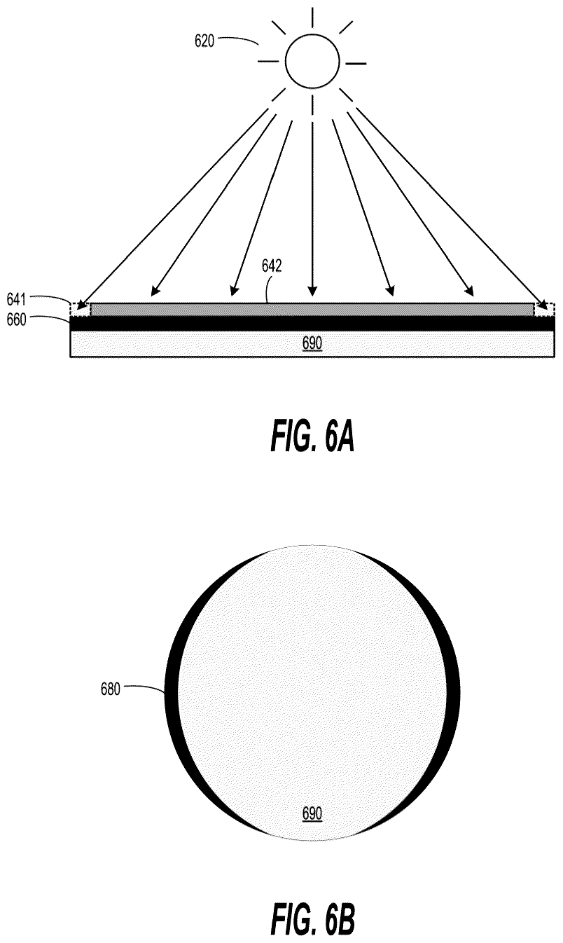

In another embodiment, a shape control layer may be formed in a negative manner at the edge region of a wafer. For example, as shown in FIGS. 6A and 6B a shape control material 660 (e.g., the shape control material 460 and the first and second shape control materials 561 and 562) can be formed by a film formation device (e.g., the film formation devices 324, 424 and 524) on the entire surface (e.g., the backside surface) of a wafer 690 (e.g., the wafers 390, 490 and 590) that is placed on a chuck (such as a vacuum spin chuck, e.g., the chucks 329, 429 and 529) to cover the entire backside surface of the wafer 690, including a portion of the backside surface at the edge region of the wafer 690 on which a shape control layer 680 (e.g., the shape control layer 480 and the first and second shape control layer 581 and 582) is to be formed; a first resist layer 641 that is the same in shape as the shape control layer 680 can be formed by the film formation device on the backside surface at the edge region of the wafer 690; a second resist layer 642 that is etched selectively with respect to the first resist layer 641 can be formed by the film formation device to cover the shape control material 660; the first resist layer 641 can be etched and removed to uncover a portion of the shape control material 660 that is to be formed as the shape control layer 680, with the second resist layer 642 intact acting as a mask; an activation device 620 (e.g., the radiation source 326, the heating units 327 and the laser source 328) can be used to provide a certain pattern of activation (e.g., radiations of variable intensities, a certain pattern of heat, and localized heat) to the uncovered portion of the shape control material 660 such that the stresses of the portion of shape control material 660 can be modified to become compressive or tensile and the corresponding shape control layer 680 that may be compressive or tensile can be formed; and the second resist layer 642 can be etched and removed.

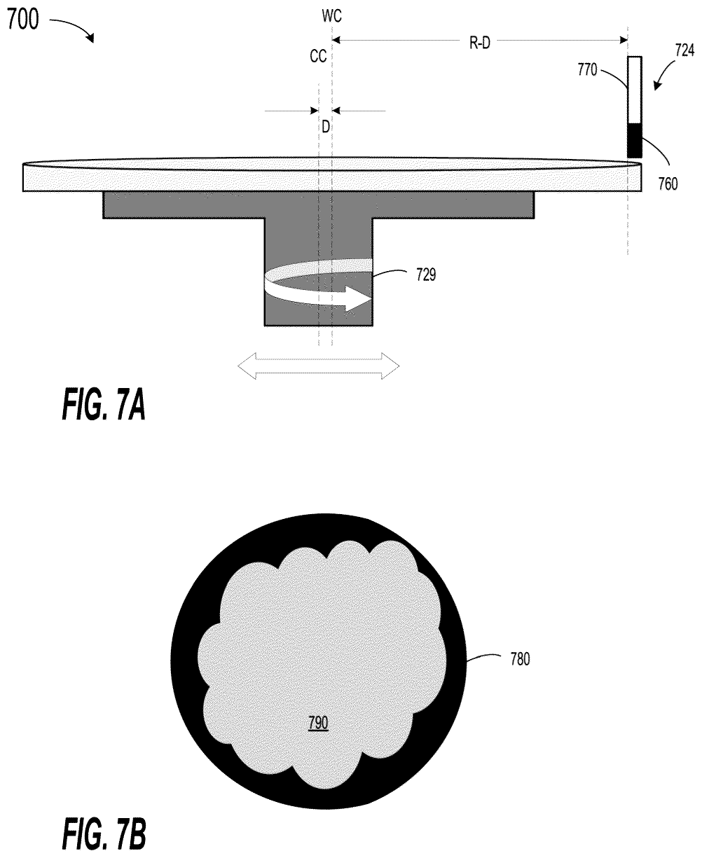

FIGS. 7A and 7B illustrate an exemplary apparatus 700 for forming a shape control layer 780 at an edge region of a wafer 790 (e.g., the wafers 390, 490, 590 and 690) according to some embodiments of the present disclosure. In an embodiment, the apparatus 700 can include a film formation device 724 (e.g., the film formation devices 324, 424 and 524) that is configured to dispense a material (e.g., a shape control material) (e.g., via a dispense nozzle 770) and form a film (e.g., the shape control layer 780) on a surface (e.g., a backside surface) of the wafer 790, and a chuck 729 (such as a vacuum spin chuck, e.g., the vacuum spin chucks 329, 429 and 529) that is configured for a wafer, e.g., the wafer 790, to be placed thereon. In some embodiments, the wafer 790 can be placed off-center on the chuck 729, and the chuck 729 and the film formation device 724 (and the wafer 790 and the dispense nozzle 770 as well) can rotate with respect to each other. In addition to rotation, in some embodiments the chuck 729 (and the wafer 790 as well) can be further configured to move with respect to the film formation device 724 (and the dispense nozzle 740 as well) while rotating. For example, the chuck 729 can vibrate with respect to the film formation device 724 while rotating. As another example, the chuck 729 or the film formation device 724 can move along a predetermined track while the chuck 729 is rotating. Therefore, the shape control layer 780 thus formed can have a shape that may depend on the offset (e.g., the offset D and the first and second offsets D1 and D2) at which the center CC of the chuck 729 is separated from the center WC of the wafer 790, the positions (e.g., the first to fourth positions A-D) of the wafer 790 where the center WC of the wafer 790 is spaced from the dispense nozzle 770 at a certain distance, and the rotation speed and movement (e.g., vibration) amplitude of the chuck 729 with respect to the film formation device 724.

Aspects of the present disclosure provide an apparatus (e.g., the apparatuses 400, 500 and 700) for forming a shape control layer (e.g., the shape control layers 480 and 780 and the first and second shape control layers 581 and 582) at the edge region of a wafer (e.g., the wafers 390, 490, 590, 690 and 790). For example, the apparatus can include a chuck (e.g., the chucks 429, 529 and 729) configured for a wafer to be off-center placed thereon with respect to a rotational axis of the chuck. The apparatus can also include a film formation device (e.g., the film formation devices 324, 424, 524 and 724) configured to dispense on a surface (e.g., the backside surface) of the wafer a shape control material (e.g., the shape control materials 460, 660 and 760 and the first and second control materials 561 and 562) that has its internal stress modified when reactive to a certain type of reaction (e.g., the radiations of variable intensities generated by the radiation source 326, the certain pattern of heat generated by the heating units 327, and the localized heat generated by the laser source 328). The chuck can be configured to rotate with respect to the film formation device. In an embodiment, the internal stress of the shape control material can be modified to become compressive. In another embodiment, the internal stress of the shape control material can be modified to become tensile. In some embodiments, the internal stress of a first portion of the shape control material is modified to become tensile, and the internal stress of a second portion of the shape control material is modified to become compressive.

In an embodiment, the wafer can be placed on the chuck such that a wafer center of the wafer is located at a first location or a second location with respect to a chuck center of the chuck, as shown in FIGS. 5A and 5B. For example, the first location and the second location can be separated from the chuck center of the chuck at a same distance. As another example, the first location and the second location can be separated from the chuck center of the chuck at different distances. For example, the first location and the second location can be arranged in a line that passes the chuck center of the chuck. As another example, the first location and the second location can be arranged in a line that does not pass the chuck center of the chuck.

In an embodiment, the chuck can be further configured to move with respect to the film formation device, as shown in FIG. 7A. For example, the chuck can be configured to vibrate with respect to the film formation device. As another example, the chuck can be configured to move along a track with respect to the film formation device. In some embodiments, the film formation device can include a dispense nozzle that is located over an edge region of the wafer and configured to dispense the shape control material at the edge region of the wafer.

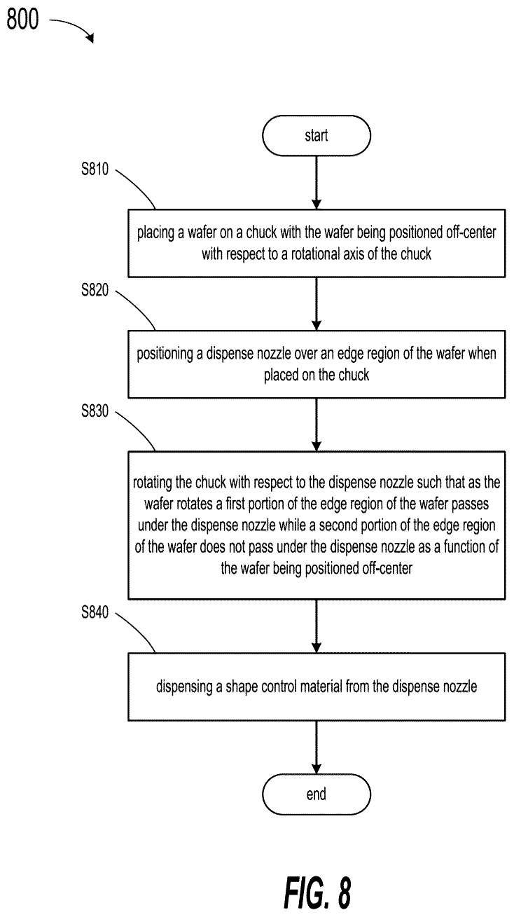

FIG. 8 is a flow chart of an exemplary method 800 for forming a shape control layer at an edge region of a wafer according to some embodiments of the present disclosure. The method 800 can be implemented by above-mentioned apparatus (e.g., the apparatuses 400, 500 and 700). The method 800 can start with step S810, at which a wafer (e.g., the wafers 390, 490, 590, 690 and 790) can be placed on a chuck (e.g., the chucks 429, 529 and 729) with the wafer being positioned off-center with respect to a rotational axis of the chuck. The method 800 can proceed to step S820.

At step S820, a dispense nozzle (e.g., the dispense nozzles 470, 570 and 770) can be positioned over an edge region of the wafer when placed on the chuck. The method 800 can proceed to step S830.

At step S830, the chuck can be rotated with the wafer placed thereon with respect to the dispense nozzle such that as the wafer rotates a first portion of the edge region of the wafer (e.g., where the first shape control layer 581 is formed) passes under the dispense nozzle while a second portion of the edge region of the wafer (e.g., the opposite to the first portion) does not pass under the dispense nozzle as a function of the wafer being positioned off-center. In an embodiment, the first portion and the second portion can have a same maximum width (e.g., the first offset D1 is equal to the second offset D2). In another embodiment, the first portion and the second portion can have different maximum widths. In some embodiments, the first portion and the second portion can be opposite to each other. In an embodiment, rotating the chuck with the wafer placed thereon with respect to the dispense nozzle can include rotating and moving the chuck with the wafer placed thereon with respect to the dispense nozzle. In another embodiment, rotating and moving the chuck with the wafer placed thereon with respect to the dispense nozzle can include rotating and vibrating the chuck with the wafer placed thereon with respect to the dispense nozzle. In some embodiments, the chuck can be moved along a track with respect to the dispense nozzle includes. The method 800 can proceed to step S840.

At step S840, a shape control material can be dispensed from the dispense nozzle, the shape control material coating a surface of the first portion of the edge region without coating the second portion of the edge portion.

In an embodiment, the wafer can be placed on the chuck such that a wafer center of the wafer is located at a first location or a second location with respect to a chuck center of the chuck. In another embodiment, the method can also include dispensing the shape control material from the dispense nozzle, the shape control material coating a surface of the second portion of the edge portion.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. An apparatus of processing a wafer, comprising:
a chuck configured for a wafer to be off-center placed thereon with respect to a rotational axis of the chuck; and
a film formation device configured to dispense on a surface of the wafer a shape control material that has its internal stress modified when reactive to a certain type of reaction,
wherein the chuck is configured to rotate with respect to the film formation device.

2. The apparatus of claim 1, wherein the wafer is placed on the chuck such that a wafer center of the wafer is located at a first location or a second location with respect to a chuck center of the chuck.

3. The apparatus of claim 2, wherein the first location and the second location are separated from the chuck center of the chuck at a same distance.

4. The apparatus of claim 2, wherein the first location and the second location are separated from the chuck center of the chuck at different distances.

5. The apparatus of claim 2, wherein the first location and the second location are arranged in a line that passes the chuck center of the chuck.

6. The apparatus of claim 2, wherein the first location and the second location are arranged in a line that does not pass the chuck center of the chuck.

7. The apparatus of claim 1, wherein the chuck is further configured to move with respect to the film formation device.

8. The apparatus of claim 7, wherein the chuck is configured to vibrate with respect to the film formation device.

9. The apparatus of claim 7, wherein the chuck is configured to move along a track with respect to the film formation device.

10. The apparatus of claim 1, wherein the film formation device includes a dispense nozzle that is located over an edge region of the wafer and configured to dispense the shape control material at the edge region of the wafer.

11. The apparatus of claim 1, wherein the internal stress of a first portion of the shape control material is modified to become tensile, and the internal stress of a second portion of the shape control material is modified to become compressive.

12. A method of processing a wafer, comprising:
placing a wafer on a chuck with the wafer being positioned off-center with respect to a rotational axis of the chuck;
positioning a dispense nozzle over an edge region of the wafer when placed on the chuck;
rotating the chuck with the wafer placed thereon with respect to the dispense nozzle such that as the wafer rotates a first portion of the edge region of the wafer passes under the dispense nozzle while a second portion of the edge region of the wafer does not pass under the dispense nozzle as a function of the wafer being positioned off-center; and
dispensing a shape control material from the dispense nozzle, the shape control material coating a surface of the first portion of the edge region without coating the second portion of the edge region.

13. The method of claim 12, wherein the first portion and the second portion have a same maximum width.

14. The method of claim 12, wherein the first portion and the second portion have different maximum widths.

15. The method of claim 12, wherein the first portion and the second portion are opposite to each other.

16. The method of claim 12, wherein rotating the chuck with the wafer placed thereon with respect to the dispense nozzle includes rotating and moving the chuck with the wafer placed thereon with respect to the dispense nozzle.

17. The method of claim 16, wherein rotating and moving the chuck with the wafer placed thereon with respect to the dispense nozzle includes rotating and vibrating the chuck with the wafer placed thereon with respect to the dispense nozzle.

18. The method of claim 16, wherein the chuck is moved along a track with respect to the dispense nozzle includes.

19. The method of claim 12, wherein the wafer is placed on the chuck such that a wafer center of the wafer is located at a first location or a second location with respect to a chuck center of the chuck.

20. The method of claim 19, further comprising:
dispensing the shape control material from the dispense nozzle, the shape control material coating a surface of the second portion of the edge region.
